(19) United States
(12) Patent Application Publication
(10) Pub. No.: US 2006/0202278 A1
(43) Pub. Date: Sep. 14, 2006

(54) SEMICONDUCTOR INTEGRATED CIRCUIT AND CMOS TRANSISTOR

(75) Inventors: Masashi Shima, Kawasaki (JP); Yosuke Shimamune, Kawasaki (JP); Akiyoshi Hatada, Kawasaki (JP); Akira Katakami, Kawasaki (JP); Naoyoshi Tamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/138,644

(22) Filed: May 27, 2005

(30) Foreign Application Priority Data
Mar. 9, 2005 (JP) 2005-066028

(51) Int. Cl. H01L 29/94

(52) U.S. Cl. 257/369; 257/374; 257/E27.046

(57) ABSTRACT

A p-channel MOS transistor includes first and second SiGe mixed crystal regions formed epitaxially to a silicon substrate at respective outer sides of sidewall insulation films of a gate electrode so as to fill respective trenches formed in source and drain diffusion regions of p-type respectively, wherein the p-channel MOS transistor further includes a compressive stressor film covering the silicon substrate and the sidewall insulation films continuously.

### CROSS-REFERENCE TO RELATED APPLICATION

The present application is based on Japanese priority application No. 2005-066028 filed on Mar. 9, 2005, the entire contents of which are hereby incorporated by reference.

### BACKGROUND OF THE INVENTION

The present invention generally relates to semiconductor devices and more particularly to a semiconductor device having improved operational speed as a result of application of stress.

With progress in the art of device miniaturization, it is now becoming possible to realize ultrafine and ultra fast semiconductor devices having a gate length of 100 nm or less.

With such ultrafine and ultra fast transistors, the area of the channel region right underneath the gate electrode is much smaller than conventional semiconductor devices, and thus, the mobility of electrons or holes traveling through the channel region is influenced heavily by the stress applied to such a channel region.

Thus, various attempts have been made for optimizing the stress applied to the channel region in the prospect of improving the operational speed of the semiconductor device further.

### REFERENCES

(Patent Reference 1) Japanese Laid-Open Patent Application 2003-86708
(Patent Reference 2) WO2002/043151
(Non-Patent Reference 1) Shimizu, A., et al., IEDM Tech. Dig. p. 433, 2001
(Non-Patent Reference 2) Nakahara, Y., et al., IEDM Tech. Dig. p. 281, 2003
(Non-Patent Reference 3) Chen, C., et al., 2004 Symposium on VLSI technology Digest of Technical Papers, pp. 56-57
(Non-Patent Reference 4) Ghani, T., et al., IEDM 2003, 978-980, Jun. 10, 2003
(Non-Patent Reference 5) Ota, K., IEDM Tech. Dig. p. 27, 2004
(Non-Patent Reverence 6) Pidin, S., et al., IEDM Tech. Dig. p. 213, 2004

### SUMMARY OF THE INVENTION

In a first aspect of the present invention, there is provided a semiconductor integrated circuit device, comprising:

a silicon substrate defined with a first device region and a second device region;

an n-channel MOS transistor formed on said first device region; and

a p-channel MOS transistor formed on said second device region,

said n-channel MOS transistor comprising: a first gate electrode carrying first sidewall insulation films on respective sidewall surfaces thereof; and source and drain diffusion regions of n-type formed in said first device region at respective outer sides of said first sidewall insulation films,

said p-channel MOS transistor comprising: a second gate electrode carrying second sidewall insulation films on respective sidewall surfaces thereof; source and drain diffusion regions of p-type formed in said second device region at respective outer sides of said second sidewall insulation films; and first and second SiGe mixed crystal regions formed in said second device region at respective outer sides of said second sidewall insulation films with epitaxial relationship to said silicon substrate, said first and second SiGe mixed crystal regions filling trenches respectively formed so as to be included in said source and drain diffusion regions of p-type,

wherein there is formed a tensile stressor film accumulating therein a tensile stress on said second device region so as to cover a surface of said silicon substrate and said first sidewall insulation films continuously, and

wherein there is formed a compressive stressor film accumulating therein a compressive stress on said first device region so as to cover said surface of said silicon substrate and said second sidewall insulation films continuously.

In another aspect of the present invention, there is provided a p-channel MOS transistor, comprising:

a silicon substrate;

a gate electrode carrying sidewall insulation films on respective sidewall surfaces thereof; and

source and drain diffusion regions of p-type formed in said silicon substrate at respective outer sides of said sidewall insulation films,

said p-channel MOS transistor further comprising first and second SiGe mixed crystal regions formed epitaxially to said silicon substrate at respective outer sides of said sidewall insulation films so as to fill respective trenches, said trenches being formed so as to be included in said source and drain diffusion regions of p-type respectively,

wherein said p-channel MOS transistor further comprises a compressive stressor film accumulating therein a compressive stress such that said compressive stressor film covers a surface of said silicon substrate and at least a surface of said sidewall insulation films continuously,

said compressive stressor film accumulating a compressive stress with a magnitude of 400 MPa or more,

said compressive stressor film exerting an in-plane compressive stress with a magnitude of 100 MPa or more in a channel region of said p-channel MOS transistor,

said first and second SiGe mixed crystal regions exerting a uniaxial compressive stress to said channel region of said p-channel MOS transistor in a channel direction.

According to the present invention, it becomes possible to improve the hole mobility of a p-channel MOS transistor formed in the second device region and hence the operational speed thereof, by forming the first and second SiGe mixed crystal regions in the source and drain diffusion regions of p-type, such that there is induced a strain in the Si crystal constituting the channel region of the p-channel MOS transistor similarly to the case of applying a uniaxial compressive stress in the direction parallel to the substrate surface as in the case of FIG. 2. At the same time, the present invention urges the first gate electrode to the channel region of the n-channel MOS transistor, by forming the tensile stressor film in the first device region so as to cover the first sidewall insulation films provided on the first gate electrode. Thereby, there is induced a strain equivalent to the case in which an in-plane tensile stress is applied to the Si crystal that constitutes the channel region of the n-channel MOS transistor, and as a result, the operational speed of the n-channel MOS transistor is improved similarly to the case of FIG. 1. Thereby, the present invention induces a strain in the Si crystal constituting the channel region of the p-channel MOS transistor similarly to the case in which there is applied an in-plane compressive stress thereto, by forming a compressive stressor film in the device region of the p-channel MOS transistor such that the compressive stressor film covers the second sidewall insulation films on the second gate electrode and such that there is applied a tensile stress to the channel region of the p-channel MOS transistor in the direction perpendicularly to the substrate surface by way of the second gate electrode.

With such a construction, it should be noted that there is induced an in-plane compressive stress parallel to the substrate surface to the channel region of the p-channel MOS transistor, in addition to the uniaxial compressive stress induced by the foregoing first and second SiGe mixed crystal regions, wherein the investigation made by the inventor of the present invention and constituting the foundation of the present invention has revealed the fact that the hole mobility of the p-channel MOS transistor, and hence the ON-current of the p-channel MOS transistor, becomes larger than a simple sum of the effect of the uniaxial compressive stress and the effect of the in-plane compressive stress. The present invention is based on this discovery.

Other objects and further features of the present invention will become apparent from the following detailed description when read in conjunction with the attached drawings.

### BRIEF DESCRIPTION OF THE DRAWINGS

FIG. 1 is a diagram explaining the principle of a conventional strained n-channel MOS transistor;

FIG. 2 is a diagram showing the principle of a conventional strained p-channel MOS transistor;

FIG. 3 is a diagram showing the construction of a CMOS device according to a first embodiment of the present invention;

FIG. 4 is a diagram explaining the effect of the present invention; and

FIGS. 5-13 are diagrams showing the fabrication process of a CMOS device according to a second embodiment of the present invention.

### DETAILED DESCRIPTION OF THE PREFERRED EMBODIMENT

Conventionally, there is proposed a structure for improving the operational speed of an n-channel MOS transistor by forming a stressor film typically of SiN accumulating therein a tensile stress in a device region of an n-channel MOS transistor so as to include the gate electrode for improvement of electron mobility in the channel region right underneath the gate electrode.

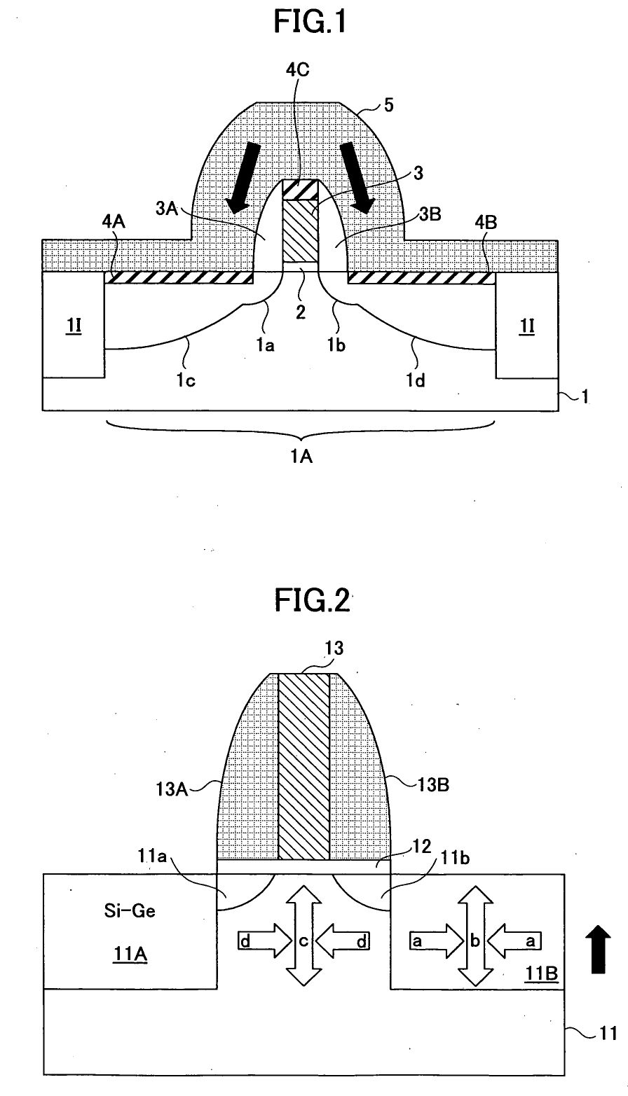

FIG. 1 shows the schematic construction of an n-channel MOS transistor having such a stressor film.

Referring to FIG. 1, a device region 1A of the n-channel MOS transistor is formed on a silicon substrate 1 by a STI device isolation region 1I in the form of a p-type well, and a gate electrode 3 is formed on the silicon substrate 1 in the device region 1A in correspondence to the channel region via a gate insulation film. Further, source and drain extension regions 1a and 1b of n-type are formed in the silicon substrate 1 at both lateral sides of the gate electrode 3.

Further, sidewall insulation films 3A and 3B are formed at respective sidewall surfaces of the gate electrode 3, and source and drain extension regions 1c and 1d of n⁺-type are formed in the silicon substrate at respective outer sides of the sidewall insulation films 3A and 3B so as to overlap with the drain extension regions 1a and 1b.

Further, silicide layers 4A and 4B are formed on the respective surface parts of the source and drain diffusion regions 1c and 1d, and a silicide layer 4C is formed further on the gate electrode 3.

Further, with the construction of FIG. 1, there is formed an SiN film 5 accumulating therein a tensile stress on the silicon substrate 1 so as to cover a gate structure that includes the gate electrode 13, the sidewall insulations 3A and 3B and further the silicide layer 4.

It should be noted that such a stressor film 5 urges the gate electrode 3 toward the silicon substrate 1, and as a result, there is induced a compressive stress in the channel region right underneath the gate electrode 3 in the direction perpendicular to the substrate surface. With this, a tensile stress is induced in the direction parallel to the substrate surface (in-plane tensile stress).

With such a construction, symmetry of the Si crystal constituting the channel region is modulated locally, resulting in suppressing of electron scattering between crystallographically equivalent states, and there are caused an increase of electron mobility and corresponding improvement of operational speed in such an n-channel MOS transistor.

With the case of p-channel MOS transistors, on the other hand, it is known that the mobility of carriers is improved by applying a uniaxial compressive stress to the channel region, and there is a proposal to use the construction of FIG. 2 as the means of applying the compressive stress to the channel region.

Referring to FIG. 2, there is formed a gate electrode 13 on a silicon substrate 11 via a gate insulation film 12, and p-type diffusion regions 11a and 11b are formed in the silicon substrate 11 at both lateral sides of the gate electrode 13 so as to define the channel region. Further, sidewall insulation films 13A and 13B are formed on the sidewall surfaces of the gate electrode 13 so as to cover also a surface part of the silicon substrate 11.

Thereby, the diffusion regions 11a and 11b function respectively as a source extension region and a drain extension region of the MOS transistor, and the flow of the holes transported through the channel region right underneath the gate electrode 13 from the diffusion region 11a to the diffusion region 11b is controlled by the gate voltage applied to the gate electrode 13.

Further, there are formed SiGe mixed crystal regions 11A and 11B in the silicon substrate 11 in the construction of FIG. 2 at respective outer sides of the sidewall insulation films 13A and 13B with epitaxial relationship with the silicon substrate 11, and p-type source and drain regions are formed in the SiGe mixed crystal regions 11A and 11B respectively in continuation from the diffusion region 11a and the diffusion region 11b.

Because the SiGe mixed crystal regions 11A and 11B have a larger lattice constant larger than that of the silicon substrate 11 in the MOS transistor of the construction of FIG. 2, the SiGe mixed crystal regions 11A and 11B are applied with a compressive stress shown in FIG. 2 by an arrow a, and as a result, the SiGe mixed crystal regions 11A and 11B undergo deformation in the direction generally perpendicular to the surface of the silicon substrate 11 as shown by an arrow b.

Because the SiGe mixed crystal regions 11A and 11B are formed on the silicon substrate 11 in epitaxial relationship therewith, such a deformation of the SiGe mixed crystal regions 11A and 11B represented by the arrow b induces a corresponding deformation in the channel region of the silicon substrate as represented by an arrow c, while such deformation of the channel region induces a shrinkage in the silicon substrate 11 in the channel direction, resulting in a state equivalent to the case a uniaxial compressive stress is applied to the channel region as represented by an arrow d.

As a result of such a uniaxial compressive stress applied to the channel region of the MOS transistor of FIG. 2, the symmetry of the Si crystal constituting the channel region is locally modulated, and as a result of such local modulation of the symmetry, degeneration of heavy holes and light holes in the valence band is resolved. Thereby, there is caused increase of hole mobility in the channel region, leading to improvement of operational speed of the transistor.

It should be noted that such increase of hole mobility caused in the channel region by locally induced stress appears particularly conspicuously in the ultrafine semiconductor devices having a gate length of 100 nm or less.

Thus, in the case such an n-channel MOS transistor and a p-channel MOS transistor are formed on a common silicon substrate to form a CMOS device, or the like, the tensile stressor film 5 of FIG. 1 functions to suppress the deformation represented by the arrow c in the channel region of the p-channel MOS transistor, and as a result, not only that the desired improvement of the hole mobility is obtained but there is caused unwanted decrease of the hole mobility, resulting in degradation in the operational speed of the p-channel MOS transistor.

In semiconductor devices that use a silicon substrate for the channel, mobility of holes is generally smaller than the mobility of electrons, and thus, it is an important issue in the designing of a semiconductor integrated circuit that includes a CMOS device to improve the operational speed of the p-channel MOS transistor, which uses holes as the carrier.

Thus, Non-Patent Reference 1 proposes a structure in which the stress of the tensile stressor film is locally relaxed in the device region of the p-channel MOS transistor by selectively introducing Ge ions into the SiN film constituting the tensile stressor film by way of ion implantation. Further, Non-Patent Reference 2 describes a technology that reduces the compressive stress applied to the channel region of the p-channel MOS transistor by reducing the thickness of the SiN film 5 selectively in the device region of the p-channel MOS transistor.

However, these conventional technologies cannot realize satisfactory improvement of device characteristics for the p-channel MOS transistor. Even when the technology of Non-Patent Reference 4 explained with reference to FIG. 2 is combined, no further improvement of the characteristics is attained.

### First Embodiment

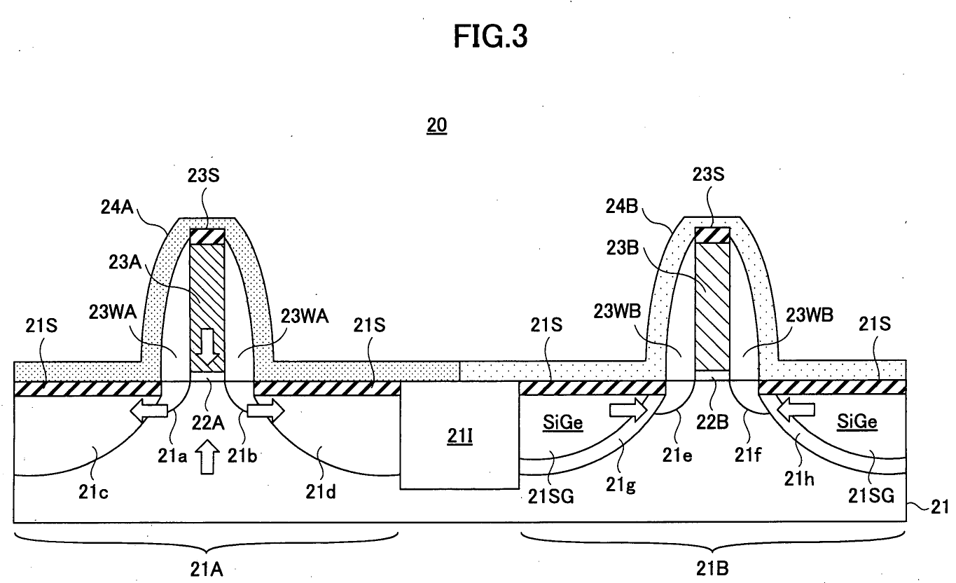

First, the principle of the present invention will be explained with reference to FIG. 3 showing the construction of a CMOS device 20 according to a first embodiment of the present invention.

Referring to FIG. 3, there are formed a device region 21A for an n-channel MOS transistor and a device region 21B for a p-channel MOS transistor on a silicon substrate 21 respectively in the form of a p-type well and an n-type well separated from each other by a STI device isolation region 21I. Further, a polysilicon gate electrode 23A of n⁺-type is formed on the device region 21A via a gate insulation film 22A of SiON, or the like, while there is formed a polysilicon gate electrode 23B of p⁺-type on the device region 21B via a gate insulation film 22B of SiON, or the like.

Further, there are formed source and drain extension regions 21a and 21b in the silicon substrate 21 forming the device region 21A at both lateral sides of the gate electrode 23A, wherein the gate electrode 23A carries, on the respective sidewall surfaces thereof, a pair of sidewall insulation films 23WA, and a pair of source and drain diffusion regions 21c and 21d of n⁺-type are formed in the part of the silicon substrate 21 corresponding to the device region 21A at respective outer sides of the sidewall insulation films 23WA.

In the device region 21B, on the other hand, there are formed source and drain extension regions 21e and 21f of p-type in the silicon substrate 21 at respective outer sides of the gate electrode 23B.

Further, the gate electrode 23B carries, on the respective sidewall surfaces thereof, a pair of sidewall insulation films 23WB, and source and drain diffusion regions 21g and 21h of p⁺-type are formed in the part of the silicon substrate 21 corresponding to the device region 21B at respective outer sides of the sidewall insulation films 23WB.

Further, there are formed silicide layers 21S on the source and drain diffusion regions 21c and 21d of n⁺-type, while a similar silicide layer 23S is formed also on the polysilicon gate electrodes 23A and 23B.

Further, in the CMOS device 20 of FIG. 3, there are formed SiGe mixed crystal regions 21SG of p-type in the device region 21B of the p-channel MOS transistor 21B so as to be included in the source diffusion region 21g and the drain diffusion region 21h of p⁺-type. Here, it should be noted that the SiGe mixed crystal regions 21SG contains Ge with a concentration of typically 20% or more in terms of atomic percent and has a lattice constant larger than that of the Si crystal constituting the silicon substrate 21.

Thus, similarly to the case explained with reference to FIG. 2, each of the SiGe mixed crystal regions 21SG undergoes dilatation in the direction perpendicular to the substrate surface as a result of the compressive stress applied thereto, while such a dilatation induces a corresponding expansion in the Si crystal constituting the silicon substrate 21 in the channel region right underneath the gate electrode 23B also in the direction perpendicular to the substrate surface. As a result, the silicon substrate undergoes contraction in the channel direction in the channel region of the p-channel MOS transistor, resulting in a strain in the channel region equivalent to the case in which a uniaxial compressive stress is applied to the channel region in the channel direction parallel to the substrate surface. Thereby, there is attained an improvement in the hole mobility in the channel region, and hence an improvement of operational speed of the p-channel MOS transistor.

Now, it should be noted that, in the CMOS device 20 of FIG. 3, there is formed a tensile stress film 24A of typically SiN accumulating therein a tensile stress on the device region 21A so as to cover the surface of the silicon substrate 21 and further the sidewall insulation films 23WA of the gate electrode 23A continuously, wherein the tensile stress film 24A shows the tendency of contraction as a result of the tensile stress accumulated therein, while such a contracting or shrinking tendency of the tensile stress film 24A urges the sidewall insulation films 23WA and hence the gate electrode 23A toward the silicon substrate 21. Thereby, there is applied a compressive stress in the device region 21A in correspondence to the channel region right underneath the gate electrode 23A in the direction perpendicular to the substrate surface as represented in the drawing by an arrow.

With this, the Si crystal constituting the channel region causes dilatation in the in-plane direction of the substrate, and there is induced a strain in the channel region similar to the case in which an in-plane tensile stress is applied thereto. As a result, in the CMOS device 20 of FIG. 3, there is achieved an improvement of electron mobility and hence an improvement of operational speed, in the n-channel MOS transistor, similarly to the case of FIG. 1.

On the other hand, the CMOS device 20 of FIG. 2 includes a compressive stressor film 24B typically of SiN and accumulating a tensile stress therein in correspondence to the device region 21B such that the compressive stressor film 24B covers the surface of the silicon substrate 21 and further the sidewall insulation films 23WB of the gate electrode 23B continuously.

Here, it should be noted that the compressive stressor film 24B shows a tendency of dilatation as a result of the compressive stress accumulated therein, and as a result, the sidewall insulation films 23WB and hence the gate electrode 23B are pulled in the direction perpendicular to the silicon substrate 21, resulting in a tensile stress in the device region 21A in correspondence to the channel region right underneath the gate electrode 23A in the direction perpendicular to he substrate surface as shown in the drawing.

With this, the Si crystal constituting the channel region causes contraction in the in-plane direction of the substrate, and there is induced a strain in the channel region similar to the case in which an in-plane compressive stress is applied to the channel region, in addition to the strain caused by the SiGe mixed crystal regions 21SG. As a result, there is achieved a further improvement of hole mobility in the p-channel MOS transistor in the CMOS device 20 of FIG. 3, similarly to the case explained with reference to FIG. 1.

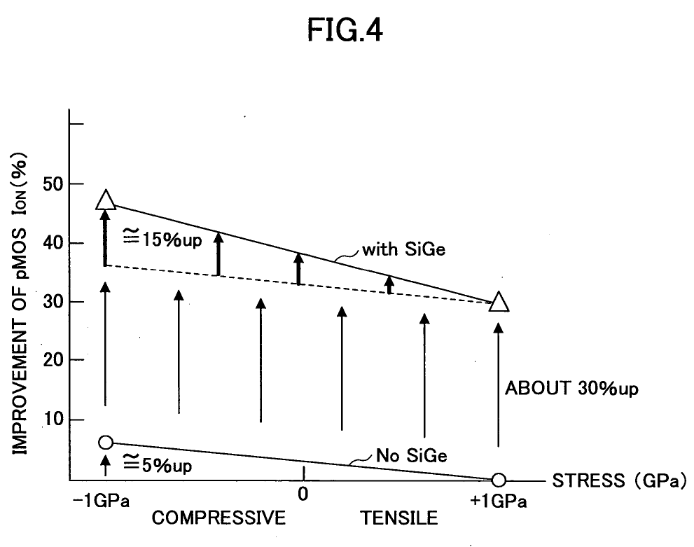

FIG. 4 shows the relationship between the ON-current of the p-channel MOS transistor and the stress caused by the stressor film 24b in the CMOS device 20 of FIG. 3, wherein it should be noted that an SiN film is used for the stressor film 24B in the experiment of FIG. 4 and that the SiN film is deposited with a condition tuned to realize the foregoing stress state.

Referring to FIG. 4, it will be noted that only 5% of improvement is achieved in the ON-current of the p-channel MOS transistor in the case in which there is formed no SiGe mixed crystal regions 21SG in the source and drain regions 21g and 21h of the p-channel MOS transistor and the compressive stress in the stressor film 24B is changed from a tensile stress of the magnitude of 1 GPa to a compressive stress of the magnitude of 1 GPa, while in the case the SiGe mixed crystal regions 21SG is formed, an improvement of 30% or more is achieved of the ON-current while using the same stressor film 24B.

Thereby, it was discovered that the effect of improvement of the ON-current of the p-channel MOS transistor by the SiGe mixed crystal regions 21SG is not added simply to the effect of improvement of the ON-current by the stressor film 24B but changes with the stress accumulated in the stressor film 24B but increases in the case the stressor film 24B accumulates therein a compressive stress and thus the stressor film 24B is a compressive stressor film. For example, an extra improvement effect of 15% can be achieved in the ON-current as compared with the case in which only the SiGe mixed crystal regions are formed, by merely accumulating a compressive stress of 1 GPa in the stressor film 24B.

Thus, with the CMOS device of FIG. 3, it becomes possible to improve the operational speed of the p-channel MOS transistor beyond the simple extrapolation of the case in which the SiGe mixed crystal regions 21SG are used and the case in which the compressive stressor film 24B is used, by forming the SiGe mixed crystal regions 21SG in the source and drain regions 21g and 21h of the p-channel MOS transistor formed in the device region 21B and further accumulating a compressive stress in the stressor film 24B formed on the device region 21B.

It should be noted that the compressive stress in such a compressive stressor film 24B, even when it has a small magnitude, causes a corresponding effect as can be seen in FIG. 4, while it is more preferable that the compressive stress in the compressive stressor film 24B has a magnitude of 400 MPa or more, so that there is induced an in-plane compressive stress of 100 MPa or more in the channel region.

It should be noted that such improvement of the operational speed of the p-channel MOS transistor is realized not only in the CMOS device shown in FIG. 3 but also in a single p-channel MOS transistor.

In FIG. 3, it should be noted that the SiGe mixed crystal regions 21SG are formed so as to be included in the source and drain regions 21g and 21h. With such a construction, it becomes possible to suppress the leakage current caused by direct contact of the p⁺-type SiGe mixed crystal regions of small bandgap with the n-type well constituting the device region 21B.

### Second Embodiment

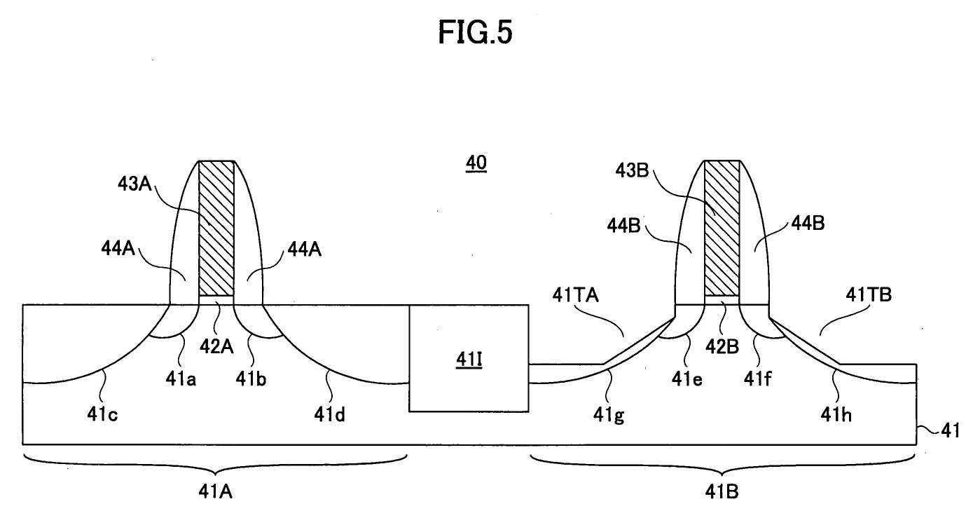

FIGS. 5-12 are diagrams showing the fabrication process of a CMOS device 40 according to a second embodiment of the present invention.

Referring to FIG. 5, there is formed an n-channel MOS transistor in a device region 41A defined on a silicon substrate 41 by an STI device isolation structure 41I such that the n-channel MOS transistor includes a polysilicon gate electrode 43A of n⁺-type, source and drain extension regions 41 and 41b of n-type and source and drain diffusion regions 41c and 41d of n⁺-type. Further, a p-channel MOS transistor is formed in a device region 41B also defined on the silicon substrate 41 by the STI device isolation structure 41I such that the p-channel MOS transistor includes a polysilicon gate electrode 43B of p⁺-type, source and drain extension regions 4e and 41f of p-type and source and drain diffusion regions 41g and 41h of p⁺-type.

Further, in the present embodiment, there are formed trenches 41TA and 41TB at the time of formation of the p-channel MOS transistor in the device region 41 but before the formation of the source and drain regions 41g and 41h of p⁺-type at the outer sides of the sidewall insulation films 44B by a self-aligned etching process that combines a dry etching process and a wet etching process while using the sidewall insulation films 44B as a mask, such that each of the trenches 41TA and 41TB is defined by plural facets.

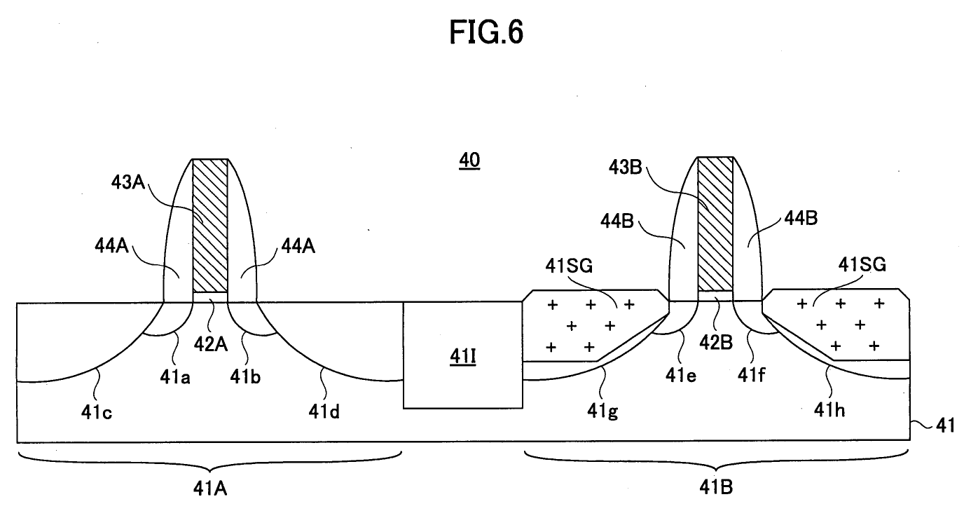

Next, in the step of FIG. 6, the SiGe mixed crystal regions 41SG of p-type epitaxially are formed so as to fill the trenches 41TA and 41TB by a low-pressure CVD process conducted at the temperature of 550° C., for example, while using SiH₄ and GeH₄ as the source gases, B₂H₆ as a dopant gas, and HCl as an etching gas.

Because the SiGe mixed crystal regions 41SG has a lattice constant larger than that of the silicon substrate 41, the SiGe mixed crystal regions 41SG thus formed undergoes dilatation in the direction perpendicular to the substrate surface, resulting in corresponding expansion of the channel region right underneath the gate electrode 43B in the direction perpendicular to the substrate surface.

As a result, the Si crystal constituting the channel region experiences a contraction in the direction parallel to the substrate surface, and there is induced a strain in the Si crystal of the channel region similarly to the case the channel region is subjected to a compressive stress from the SiGe mixed crystal regions 41SG. As a result, degeneration of heavy holes and light holes caused in the valence band is resolved in the channel region of the p-channel MOS transistor, resulting in an improvement of the hole mobility.

In the step of FIG. 6, it should be noted that each of the SiGe mixed crystal regions 41SG is grown to a level above the interface between the silicon substrate 41 and the gate insulation film 42A or 42B and is defined by facets formed of crystal surface.

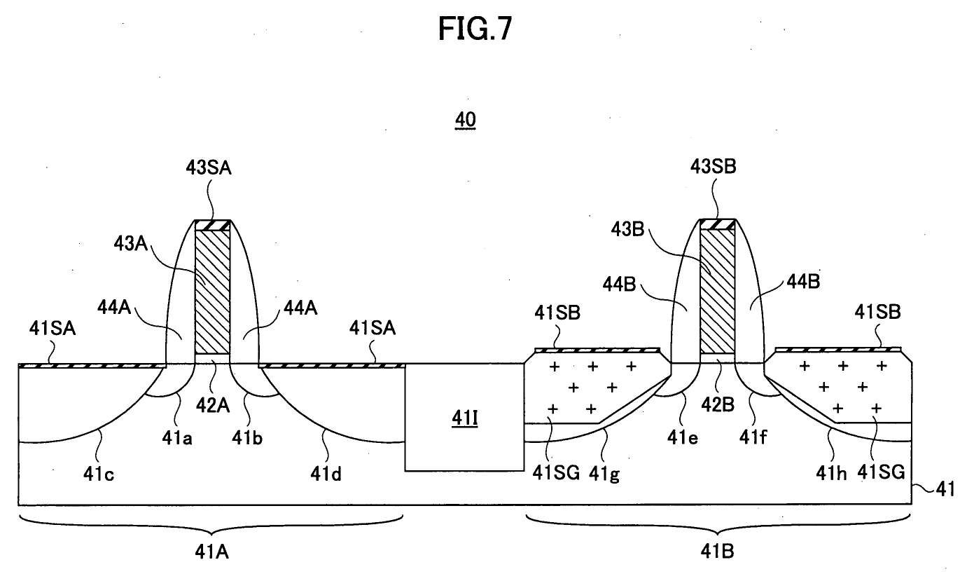

Next, in the step of FIG. 7, by conducting a salicide process, silicide layers 41SA are formed in the device region 41A on the source and drain regions 41c and 41d and silicide layers 41SB are formed in the device region 41B on the source and drain regions 41e and 41f. Further, silicide layers 43SA and 43SB are formed respectively on the polysilicon gate electrodes 43A and 43B.

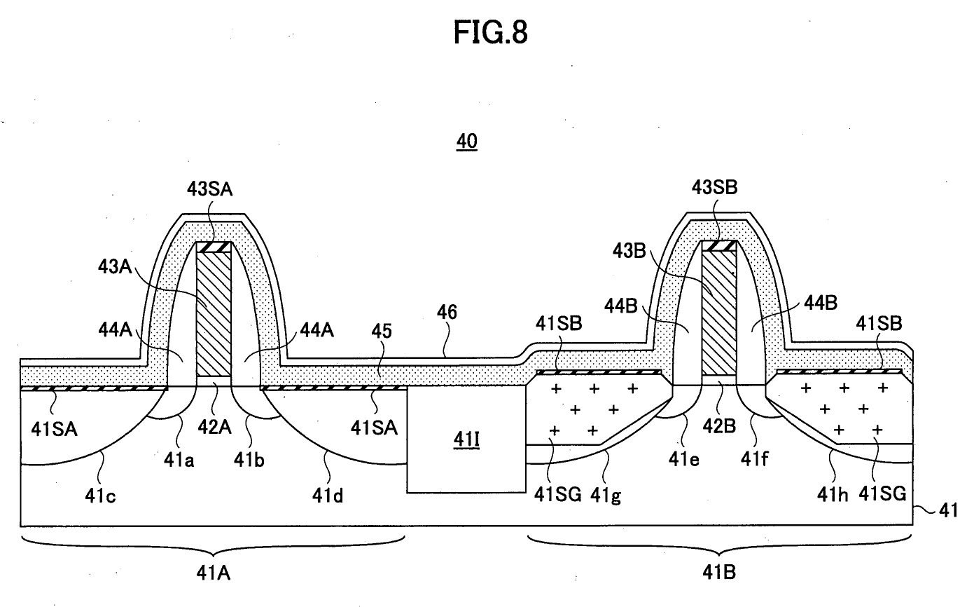

Further, in the step of FIG. 8, an SiN film 45 is deposited on the silicon substrate 41 with a thickness of about 50 nm by a low-pressure CVD process under the condition chosen such that there occurs accumulation of a tensile stress in the film, followed by formation of an SiO₂ film 46 by a CVD process as an etching stopper film. For example, the SiN film 45 may be formed under the processing pressure of 3000 Pa at the substrate temperature of 500° C. while supplying SiH₄ and NH₃ with respective flow rates of 20 SCCM and 7000 SCCM.

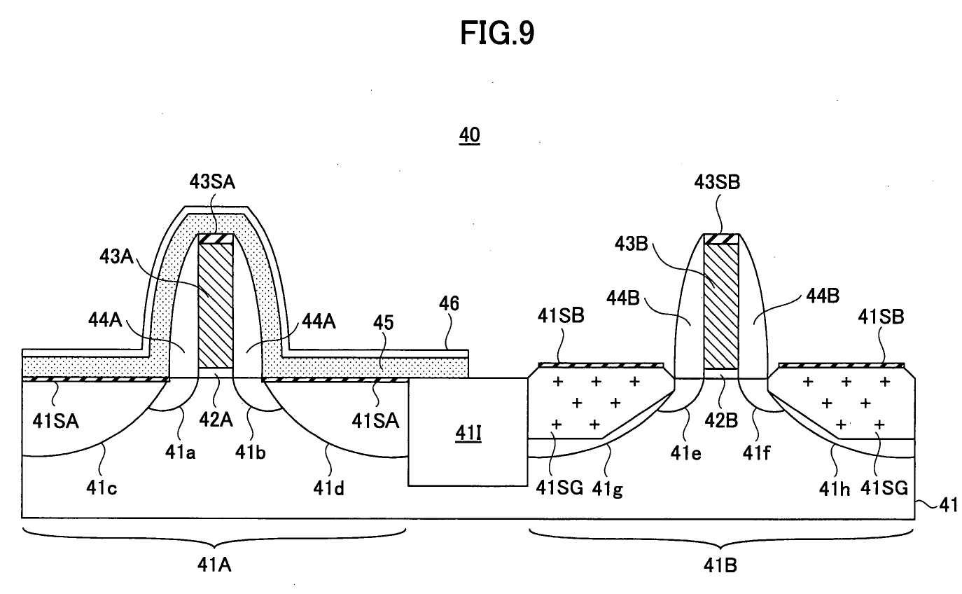

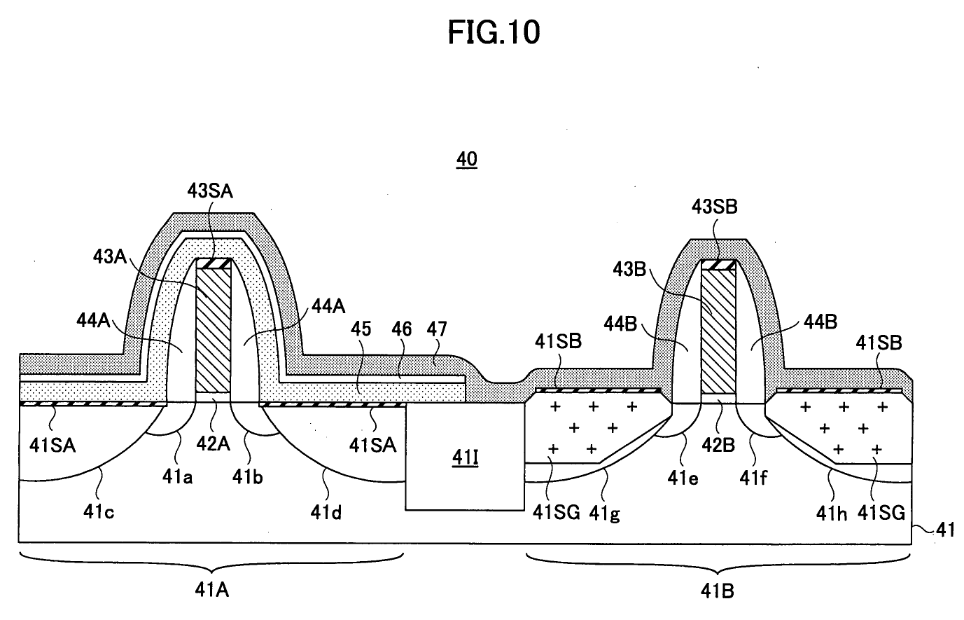

Next, in the step of FIG. 9, the SiN film 45 is removed from the device region 41B together with the SiO₂ film thereon by using a resist process, followed by deposition of an SiN film 47 in the step of FIG. 10 on the structure of FIG. 9 by a low-pressure CVD process with a thickness of about 50 nm under the condition in which there is caused accumulation of compressive stress in the film. For example, the SiN film 47 can be formed under the processing pressure of 250 Pa at the substrate temperature of 400° C. while supplying SiH₄ and NH₃ with respective flow rates of 600 SCCM and 1400 SCCM.

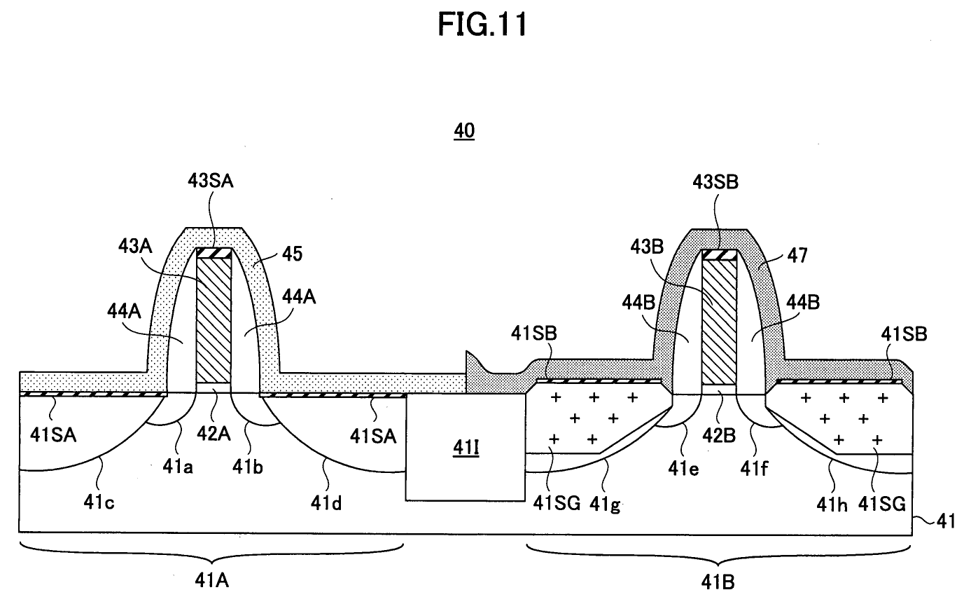

Next, in the step of FIG. 11, the SiN film 47 is removed from the device region 41A selectively to the SiO₂ film 46 in the device region 41A by using a resist process, followed by selective etching of the SiO₂ film 46 with regard to the SiN film 45 underneath the SiO₂ film 46. With this, there is formed a tensile stressor film 45 on the n-channel MOS transistor in the device region 41A and a compressive stressor film 47 on the p-channel MOS transistor in the device region 41B separated from the device region 41A by the device isolation structure 41I.

Similarly to the embodiment of FIG. 3, the present embodiment can improve the operational speed of the p-channel MOS transistor beyond a simple sum of the improvement achieved by using the SiGe mixed crystal regions 21SG alone and the improvement achieved by using the compressive stressor film 47 alone, by using the SiGe mixed crystal regions 41SG as a part of the p⁺-type source and drain diffusion regions 41g and 41h of the p-channel MOS transistor formed in the device region 41B and further by forming the compressive stressor film 47 so as to cover the surface of the silicon substrate 41 and the sidewall insulation films on the gate electrode 23B.

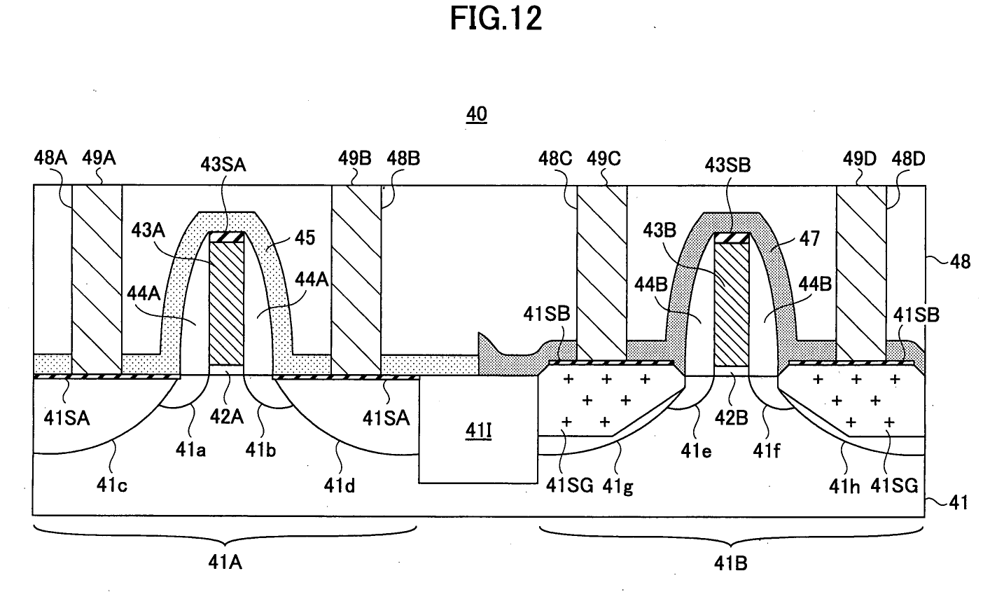

Further, in the step of FIG. 12, there is formed an interlayer insulation film 48 on the structure of FIG. 11, and contact holes 48A-48D are formed in the interlayer insulation film 48 so as to expose the silicide layer 41SA on the source region 41c, the silicide layer 41SCA on the drain region 41d, the silicide layer 41SB on the source region 41g and the silicide layer 41SB on the drain region 41h, respectively. Further, contact plugs 49A-49D are formed respectively in the contact holes 48A-48D.

In the step of FIG. 12, the tensile stressor film 45 and the compressive stressor film 47 are used also as a contact etching stopper, and thus, it is preferable that any of the tensile stressor film 45 and the compressive stressor film 47 has a film thickness of 50 nm or more.

### Third Embodiment

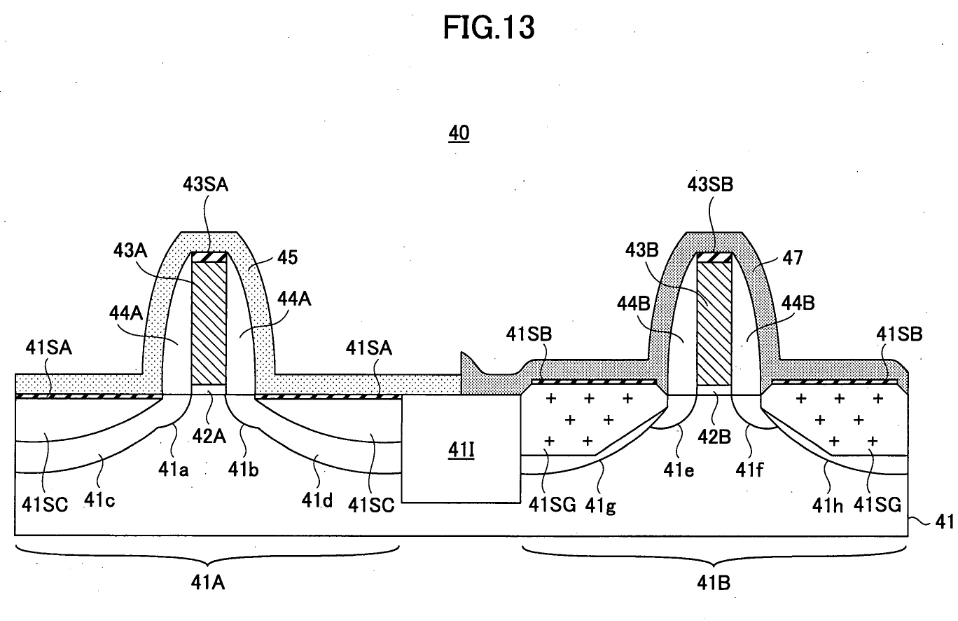

FIG. 13 shows the construction of a CMOS device 60 according to a third embodiment of the present invention, wherein those parts corresponding to the parts described previously are designated by the same reference numerals and the description thereof will be omitted.

Referring to FIG. 13, it will be noted that the p-channel MOS transistor of the present embodiment has a construction similar to that of the CMOS device 40 explained before, except that there are formed SiC regions 41SC in the source and drain regions 41c and 41d of the n-channel MOS transistor so as to be included therein, by introducing C (carbon) ions into the source and drain regions 41c and 41d by an ion implantation process.

It should be noted that the SiC regions 41C thus formed have a lattice constant smaller than that of the Si crystal constituting the silicon substrate 41, and thus, there is induced an uniaxial tensile stress acting in the channel direction in the channel region of the n-channel MOS transistor right underneath the polysilicon gate electrode 43A. Thereby, the electron mobility in the channel region of the n-channel MOS transistor is increased further, in addition to the effect of the tensile stressor film 45.

Further, with the embodiment of FIG. 13, it is possible to increase the compressive stress applied to the channel region via the gate electrode 43A in the direction perpendicular to the substrate surface, by introducing As into the gate electrode 43A with a concentration near the solubility limit of the Si crystal. By doing so, the lattice constant, and hence the volume, of the Si crystal grains constituting the polysilicon gate electrode 43A is increased, and it becomes possible to increase the magnitude of the compressive stress applied to the channel region via the gate electrode 43A in the direction perpendicular to the substrate surface can be increased further according to the mechanism explained with reference to FIG. 1. Thereby, the mobility in the channel region is increased further.

Further, with the present invention, it is also possible to cover the p-channel MOS transistor by the tensile stressor film 24A formed on the device region 21A in place of the compressive stressor film 24B and selectively introducing an element such as Ge that causes relaxation of stress in the film into the part of the film 24A in correspondence to the device region 21B by way of ion implantation process.

Further, in the present embodiment, it is possible to cover the p-channel MOS transistor in the embodiment of FIG. 3 by the tensile stressor film formed on the device region 21A in place of the foregoing compressive stressor film 24B and decrease the thickness of the tensile stressor film 24A selectively in correspondence to the device region 21B.

Further, the present invention is not limited to the embodiments described heretofore, but various variations and modifications may be made without departing from the scope of the invention.

1. A semiconductor integrated circuit device, comprising:
a silicon substrate defined with a first device region and a second device region;
an n-channel MOS transistor formed on said first device region; and
a p-channel MOS transistor formed on said second device region,
said n-channel MOS transistor comprising: a first gate electrode carrying first sidewall insulation films on respective sidewall surfaces thereof; and source and drain diffusion regions of n-type formed in said first device region at respective outer sides of said first sidewall insulation films,
said p-channel MOS transistor comprising: a second gate electrode carrying second sidewall insulation films on respective sidewall surfaces thereof; source and drain diffusion regions of p-type formed in said second device region at respective outer sides of said second sidewall insulation films; and first and second SiGe mixed crystal regions formed in said second device region at respective outer sides of said second sidewall insulation films with epitaxial relationship to said silicon substrate, said first and second SiGe mixed crystal regions filling trenches respectively formed so as to be included in said source and drain diffusion regions of p-type,
wherein there is formed a tensile stressor film accumulating therein a tensile stress on said first device region so as to cover a surface of said silicon substrate and said first sidewall insulation films continuously,
there is formed a compressive stressor film accumulating therein a compressive stress on said second device region so as to cover said surface of said silicon substrate and said second sidewall insulation films continuously, and
wherein only said silicon substrate underlies said device region and said second device region.

2. The semiconductor integrated circuit device as claimed in claim 1, wherein said tensile stressor film accumulates a tensile stress with a magnitude of 500 MPa or more.

3. The semiconductor integrated circuit device as claimed in claim 1, wherein said compressive stressor film accumulates a compressive stress with a magnitude of 400 MPa or more.

4. The semiconductor integrated circuit device as claimed in claim 3, wherein said compressive stressor film induces an in-plane compressive stress of 100 MPa or more in a channel region of said p-channel MOS transistor, in addition to a uniaxial compressive stress formed in said channel region of said p-channel MOS transistor by said first and second SiGe mixed crystal regions.

5. The semiconductor integrated circuit device as claimed in claim 1, wherein there are formed first and second SiC regions in said first device region in epitaxy to said silicon substrate at respective outer sides of said first sidewall insulation films so as to be included respectively in said source and drain diffusion regions of n-type.

6. The semiconductor integrated circuit device as claimed in claim 1, wherein said first gate electrode comprises polysilicon containing As with a concentration near a solubility limit of As in Si.

7. The semiconductor integrated circuit device as claimed in claim 1, wherein there is formed an interlayer insulation film on said silicon substrate via said tensile stressor film in said first device region, said interlayer insulation film being formed in said second device region on said silicon substrate via said compressive stressor film, wherein said interlayer insulation film is formed with first and second contact holes respectively corresponding to said source and drain diffusion regions of n-type in said first device region and third and fourth contact holes respectively corresponding to said source and drain diffusion regions of n-type in said second device region, each of said tensile stressor film and said compressive stressor film having a thickness of 40 nm or more.

8. (canceled)
